(19) United States
(12) Patent Application Publication
(10) Pub. No.: US 2015/0015248 A1
(43) Pub. Date: Jan. 15, 2015

(54) CURRENT SENSOR AND ELECTRIC POWER CONVERTER

(71) Applicants: Yusuke Seo, Kasugai-shi (JP); Kaoru Torii, Toyota-shi (JP); Kentaro Hirose, Aichi-gun (JP); Naoto Kikuchi, Seto-shi (JP); Kenichi Takagi, Nagoya-shi (JP); Kazunari Moriya, Seto-shi (JP)

(72) Inventors: Yusuke Seo, Kasugai-shi (JP); Kaoru Torii, Toyota-shi (JP); Kentaro Hirose, Aichi-gun (JP); Naoto Kikuchi, Seto-shi (JP); Kenichi Takagi, Nagoya-shi (JP); Kazunari Moriya, Seto-shi (JP)

(73) Assignee: TOYOTA JIDOSHA KABUSHIKI KAISHA, Toyota-shi, Aichi-ken (JP)

(21) Appl. No.: 14/377,823

(22) PCT Filed: Feb. 23, 2012
(86) PCT No.: PCT/JP2012/054426

§ 371 Date: Aug. 8, 2014

(51) Int. Cl. G01R 33/032; G01R 31/34; G01R 31/327

(52) U.S. Cl. CPC G01R 33/032; G01R 31/327; G01R 31/34
USPC 324/244.1

(57) ABSTRACT

An art of measuring a current with a suppressed influence of a switching noise is provided. The art disclosed by the present specification is a current sensor that measures an output current of a switching circuit. The current sensor is equipped with a magneto-optical element that is arranged at a current measurement point, a light source that radiates light onto the magneto-optical element, and a light receiver that receives transmitted light or reflected light of the magneto-optical element. The light source radiates light in synchronization with a carrier signal of the switching circuit. Light is radiated in synchronization with the carrier signal, and a current is measured with the aid of the light. Due to synchronization with the carrier signal, the current can be measured at timings other than a switching timing resulting from a PWM signal that is generated on the basis of the carrier signal.

### TECHNICAL FIELD

The art disclosed by the present specification relates to a current sensor suited to measure an output current of a switching circuit, and an electric power converter that includes such a current sensor. The current sensor disclosed by the present specification utilizes a magneto-optical element (magneto-optical crystal).

### BACKGROUND ART

A current sensor employing a magneto-optical element is an example of devices for accurately measuring a current within an extremely short time. The current sensor is basically constituted of the magneto-optical element that is arranged at a current measurement point, a laser light source that irradiates the magneto-optical element with a laser, a laser receiver that receives a laser reflected by (or a laser transmitted through) the magneto-optical element, and a calculation unit that calculates a value of the current at the measurement point from a polarization state of the received laser.

The magneto-optical element has the specification of changing the polarization state of reflected light or transmitted light in accordance with the received magnetic field. Accordingly, the magneto-optical element is arranged within the magnetic field generated by the current, and a laser is radiated onto the magneto-optical element, so that the magnitude of the current can be obtained from the polarization state of reflected light (or transmitted light). The current sensor employing the magneto-optical element has the advantages of being able to carry out a measurement within an extremely short time (having a wide frequency band), being noninvasive, being resistant to electromagnetic noise, etc. Incidentally, the phenomenon of rotation of the plane of polarization resulting from changes in the polarization state of transmitted light due to the influence of a magnetic field is referred to as a Faraday effect, and the phenomenon of changes in the polarization state of reflected light is referred to as a magneto-optical Kerr effect.

For example, an application example of such a current sensor is disclosed in Japanese Patent Application Publication No. 6-224727 (JP-6-224727 A) (Patent Document 1). Besides, an example of such a current sensor is disclosed in Japanese Patent Application No. 2011-56473 (which had not been laid open when the present application was filed) as well. In particular, Patent Document 1 proposes the application of a current sensor employing the foregoing magneto-optical element as a current sensor that measures an output alternating current of an inverter, for the reason that the inverter of an electric vehicle or a railroad vehicle generates a strong electromagnetic noise.

### SUMMARY OF THE INVENTION

### Problem to Be Solved by the Invention

A switching operation constitutes one cause of an electromagnetic noise not only in an inverter but also in an electric power converter including a switching circuit. The art disclosed by the present specification also adopts a current sensor that utilizes a magneto-optical element. The art disclosed by the present specification takes advantage of the configuration specific to the switching circuit, and suppresses the influence of a noise resulting from the switching operation in measuring the current.

### Means for Solving the Problem

In many cases, a signal for driving a switching circuit is a PWM signal (or a PAM signal). The PWM signal is generated from a periodic signal referred to as a carrier signal and a signal referred to as a command signal (a drive signal). The command signal is equivalent to an alternating current waveform that is desired to be output. A controller for the switching circuit compares the carrier signal and the command signal with each other, and generates a variable pulse width signal whose pulse width corresponds to a period in which the voltage of one of the signals (e.g., the carrier signal) is high, namely, a PWM signal. It should be noted herein that the timing when a switching operation is performed is equivalent to an intersecting point of the carrier signal and the command signal. Then, a noise is generated as a result of the switching operation. Thus, the art disclosed by the present specification adjusts the timing for emitting a laser in such a manner as to avoid the intersecting point. Concretely, in a current sensor disclosed by the present specification, a laser light source radiates light in synchronization with a carrier signal for generating a drive signal for the switching circuit. Due to this configuration, laser light for measuring the current is radiated at timings other than the timing of the switching operation. A noise generated at the switching timing has no influence or, if any, a little influence on the measured value of the current based on such laser light.

In order to generate a pulsed laser that is synchronized with the carrier signal, for example, it is appropriate to compare the command signal with a constant voltage level and the carrier signal with each other, and radiate the laser only for a period in which the carrier signal is large (or only for a period in which the carrier signal is small). The pulsed laser for radiating the laser during the period in which the carrier signal is large is a pulsed laser that is synchronized with the peak of the carrier signal, and moreover, is a pulsed laser around the peak. On the contrary, the pulsed laser for radiating the laser during the period in which the carrier signal is small is a pulsed laser that is synchronized with the bottom of the carrier signal, and moreover, is a pulsed laser around the bottom. The use of such a pulsed laser makes it possible to measure a current except at the switching timing, and to exclude the influence of a noise resulting from switching.

Incidentally, the foregoing advantages can be obtained if the pulsed laser is triggered in the neighborhood of the peak or bottom of the carrier signal. It should therefore be noted that, for example, a laser light source that compares command vibrations at a level close to the peak (or the bottom) and a carrier signal with each other and generates a pulse only for a predetermined width of time from the timing of their intersecting point is also useful.

There are also other advantages of utilizing the carrier signal. Since the existing carrier signal is utilized, there is no need to separately prepare a periodical trigger signal for generating the pulsed laser. By using the pulsed laser instead of a continuous wave laser, the service life of the laser light source is prolonged. Besides, the heating value of the pulsed laser is smaller than the heating value of the continuous wave laser. In the case where the current sensor is used to measure alternating currents in three phases of the inverter, three alternating current signals can be measured at the same timing by generating three pulsed lasers on the basis of a single carrier signal.

The foregoing current sensor constitutes an art utilizing the properties of the switching circuit. Therefore, an electric power converter that is equipped with the foregoing current sensor and the foregoing switching circuit is also a novel device disclosed by the present specification. In particular, an inverter that is equipped with a current sensor that measures three output alternating currents, namely, a U-phase output alternating current, a V-phase output alternating current, and a W-phase output alternating current by three laser light sources that are synchronized with a single carrier signal is the most typical example of the novel device disclosed by the present specification.

The details of the art disclosed by the present specification and further improvements in this art will be described in the mode of carrying out the invention.

### BRIEF DESCRIPTION OF THE DRAWINGS

FIG. 1 is a block diagram of a drive system of a hybrid vehicle.

FIG. 2 is a block diagram of a current sensor.

FIG. 3 consists of graphs showing an example of a relationship among an output current signal including noise, a carrier signal, a pulsed laser, and a measured current value.

FIG. 4 consists of graphs showing another example of a relationship among an output current signal including noise, a carrier signal, a pulsed laser, and a measured current value.

FIG. 5 is a view illustrating a compensation for a delay in activation of an AD converter.

### MODE FOR CARRYING OUT THE INVENTION

A current sensor according to an embodiment of the invention will be described with reference to the drawings. In the present embodiment of the invention, the current sensor is applied to an inverter for driving a motor of a hybrid vehicle. The inverter is equipped with the current sensor in order to measure three output currents of the inverter, namely, a U-phase output current, a V-phase output current, and a W-phase output current.

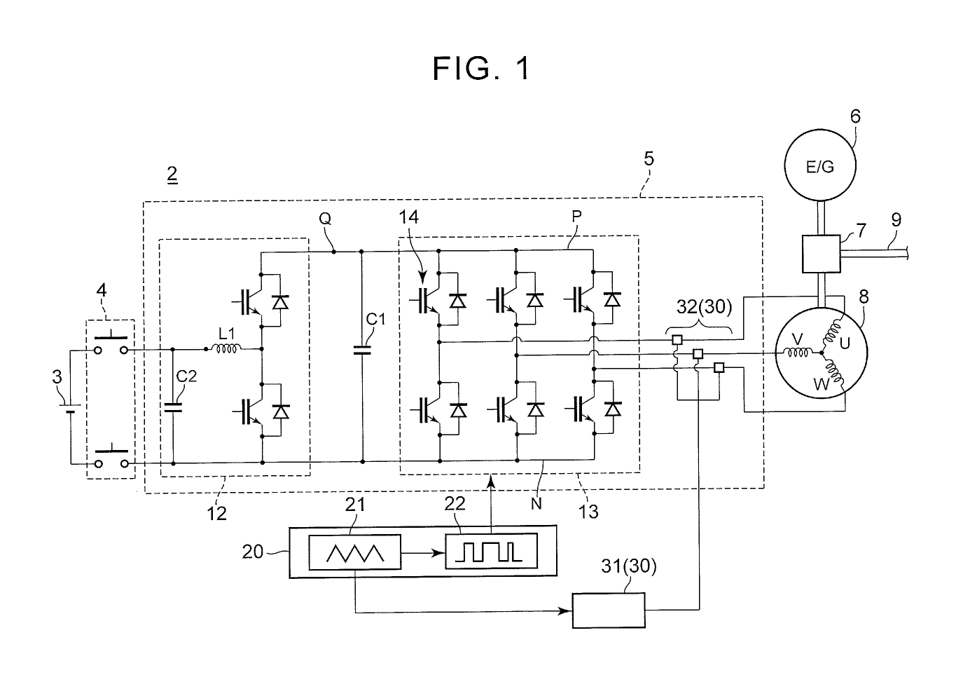

FIG. 1 is a block diagram showing a drive system of a hybrid vehicle 2. The hybrid vehicle 2 is equipped with a motor 8 and an engine 6 as drive sources for running. An output torque of the motor 8 and an output torque of the engine 6 are appropriately distributed/synthesized by a motive power distribution mechanism 7, and are transmitted to an axle 9 (i.e., wheels). Incidentally, it should be noted that only those components necessary for the description of the present specification are depicted in FIG. 1, and that some of the components that have no bearing on the description are not shown.

An electric power for driving the motor 8 is supplied from a main battery 3. The main battery 3 has an output voltage of, for example, 300 V. Incidentally, although not shown in the drawing, the hybrid vehicle 2 is equipped with an auxiliary battery for supplying electric power to a group of devices (generally referred to as “auxiliaries”) that are driven at a voltage lower than the output voltage of the main battery 3, such as a car navigation system, a room lamp and the like, as well as the main battery 3. The auxiliary battery has an output voltage (i.e., a voltage for driving the auxiliaries) of, for example, 12 V or 24 V. The appellation “main battery” is used for the sake of convenience, in order to make a distinction from “auxiliary battery”.

The main battery 3 is connected to an inverter 5 via a system main relay 4. The system main relay 4 is a switch that connects/disconnects the main battery 3 and an electric power circuit of the vehicle to/from each other. The system main relay 4 is changed over by a superordinate controller (not shown).

The inverter 5 includes a voltage converter circuit 12 that steps up the voltage of the main battery 3 to a voltage (e.g., 600 V) suited to drive the motor, and an inverter circuit 13 that converts a direct-current electric power obtained after the stepping up of the voltage into an alternating current. An output current of the inverter circuit 13 is equivalent to an electric power supplied to the motor 8. Incidentally, the hybrid vehicle 2 can also generate electricity by the motor 8, through the use of a driving force of the engine 6 or deceleration energy of the vehicle. In the case where the motor 8 generates electricity, the inverter circuit 13 converts an alternating current into a direct current, and furthermore, the voltage converter circuit 12 steps down the voltage to a voltage slightly higher than that of the main battery 3, and supplies the voltage to the main battery 3. Both the voltage converter circuit 12 and the inverter circuit 13 are circuits that are mainly constituted of switching circuits 14 such as IGBT's and the like. A controller 20 (an inverter controller) generates and supplies a control signal (a PWM signal) to each of the switching circuits 14. Incidentally, each of the switching circuits 14 is configured, concretely, by connecting an IGBT and a diode to each other in an anti-parallel manner, and the PWM signal is supplied to a gate of the IGBT. Besides, it should be noted that although the inverter 5 is equipped with a plurality of switching circuits in each of the voltage converter circuit 12 and the inverter circuit 13, only one of the switching circuits is denoted by the symbol “14” in FIG. 1.

The controller 20 includes a carrier signal generator 21 and a PWM generator 22. The carrier signal generator 21 generates triangular waves of a predetermined frequency. The PWM generator 22 compares a motor command signal (a motor drive signal) transmitted from the superordinate controller (not shown) and a carrier signal with each other, and generates a pulse signal (i.e., a PWM signal) that has, as a pulse width, a period in which the voltage of the carrier signal is higher than the voltage of the motor command signal. The controller 20 generates a PWM signal individually for each of the switching circuits. The generated PWM signal is supplied to each of the switching circuits of the inverter circuit 13.

It should be noted that although the inverter circuit 13 is equipped with the plurality of the switching circuits, there is one carrier signal.

A capacitor C2 is connected to a low-voltage side (i.e., a main battery side) of the voltage converter circuit 12, and a capacitor C1 is connected to a high-voltage side (i.e., an inverter circuit side) of the voltage converter circuit 12. The capacitor C2 is connected in parallel to the voltage converter circuit 12, and the capacitor C1 is also connected in parallel to the voltage converter circuit 12. The capacitor C2 constitutes a step-up/step-down circuit together with a reactor L1 and the switching circuits. The capacitor C2 temporarily accumulates the electric power of the main battery 3, and serves as an electric power source when the reactor L1 generates an induced electromotive force. The capacitor C2 is sometimes referred to as a filter capacitor. The capacitor C1 is inserted to smooth the current input to the inverter circuit 13, and is sometimes referred to as a smoothing capacitor. Incidentally, an electric wire on a high-potential side of a group of switching elements of the inverter circuit 13 is referred to as a P line, and an electric wire on a ground potential side of the group of the switching elements of the inverter circuit 13 is referred to as an N line. The capacitor C1 is inserted between the P line and the N line. Since a large current is supplied from the main battery 3 to the motor 8, both the capacitor C2 and the capacitor C1 are large in capacity.

In order to control the current supplied to the motor 8, the inverter 5 performs current feedback control. Thus, the inverter 5 is equipped with a current sensor 30. The current sensor 30 is constituted of a controller 31 (a sensor controller) and three sensor bodies 32. The controller 31 receives a carrier signal from a carrier signal generator 21 in the inverter controller 20, and generates a laser drive signal that is synchronized with the carrier signal. The laser drive signal is a pulse signal that is synchronized with the carrier signal. The laser drive signal is transmitted to each of the three sensor bodies 32. Each of the sensor bodies 32 irradiates a target with a pulsed laser on the basis of the laser drive signal, and receives reflected waves thereof. The target is a magneto-optical element that is installed in a current cable. Each of the sensor bodies 32 transmits a signal indicating a polarization angle of the laser reflected waves to the controller 31. The controller 31 specifies the magnitude of the current on the basis of signals transmitted from the sensor bodies 32. As shown in FIG. 1, the sensor bodies 32 are fitted to three outputs of the inverter 5, namely, a U-phase output, a V-phase output, and a W-phase output respectively.

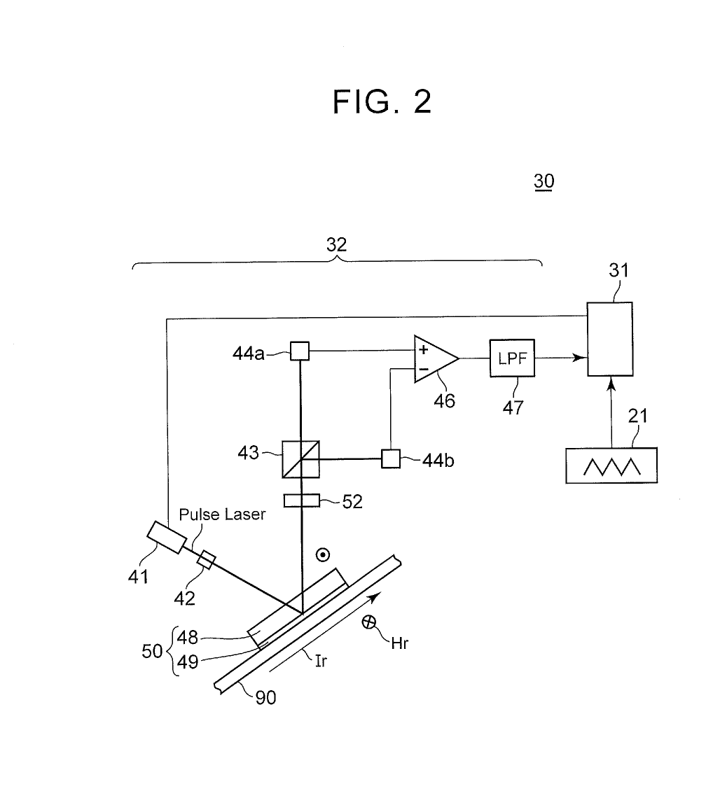

The configuration of each of the sensor bodies 32 will be described. FIG. 2 is a block diagram showing each of the sensor bodies 32. The sensor body 32 shown in FIG. 2 measures a current Ir flowing through a bus bar 90 at the U-phase output of the inverter. As described above, the controller 31 receives a carrier signal from the carrier signal generator 21, and transmits a laser drive signal synchronized with the carrier signal to a laser light source 41. The laser drive signal transmitted by the controller 31 is a pulse signal. The laser light source 41 radiates a pulsed laser on the basis of the laser drive signal generated by the controller 31. The laser drive signal will be described later in detail. The pulsed laser radiated from the laser light source 41 passes through a polarizing prism 42, and becomes a linearly polarized laser. The linearly polarized pulsed laser is radiated onto a magneto-optical element 50 (MOC) that is arranged along the bus bar 90. The magneto-optical element is an element that has the properties of changing in birefringence upon receiving a magnetic field. The magneto-optical element 50 changes the birefringence in accordance with the intensity of the received magnetic field. The polarization state of passing laser light changes through changes in the birefringence. Typically, the angle of polarization changes in accordance with the intensity of the magnetic field. It should be noted herein that a magnetic field Hr is generated as a result of the current Ir flowing through the bus bar 90. Accordingly, the intensity Hr of the magnetic field, namely, the magnitude of the current Ir can be measured by measuring the polarization state (the angle of polarization) of laser light that has passed through the magneto-optical element 50. As the magneto-optical element 50, it is appropriate to use, for example, a magneto-optical element that is obtained by coating a back surface of a Bi-YIG bulk single crystal 48 with a derivative total reflection mirror (DM) 49. Since the back surface of the Bi-YIG bulk single crystal 48 is coated with the derivative total reflection mirror 49, the pulsed laser is reflected by the magneto-optical element 50. The reflected laser light passes through a ¼ wavelength plate 52, and then is split into p-waves and s-waves by a prism beam splitter 43. Each laser light is detected by a corresponding one of laser detectors 44a and 44b. Although detailed description will be omitted, the difference between the intensity of p-waves and the intensity of s-waves is equivalent to the angle of polarization. The laser detectors 44a and 44b measure the intensity of p-waves and the intensity of s-waves respectively. Outputs of the laser detectors 44a and 44b are input to an operation amplifier 46, and the difference between the two beams of laser light is amplified. The difference between the two beams of laser light is equivalent to the magnitude of the magnetic field Hr, namely, the current Ir flowing through the bus bar 90. An output of the operation amplifier 46 is transmitted to the controller 31 via a low-pass filter 47. Incidentally, the controller 31 performs a calculation for calculating a current from the output of the operation amplifier 46. Besides, the magneto-optical element 50 may be fitted on the bus bar for measuring the current, at an arbitrary position. The position where the magneto-optical element 50 is fitted is equivalent to a measurement point. That is, the measurement point can be determined as an arbitrary position on the bus bar for measuring the current.

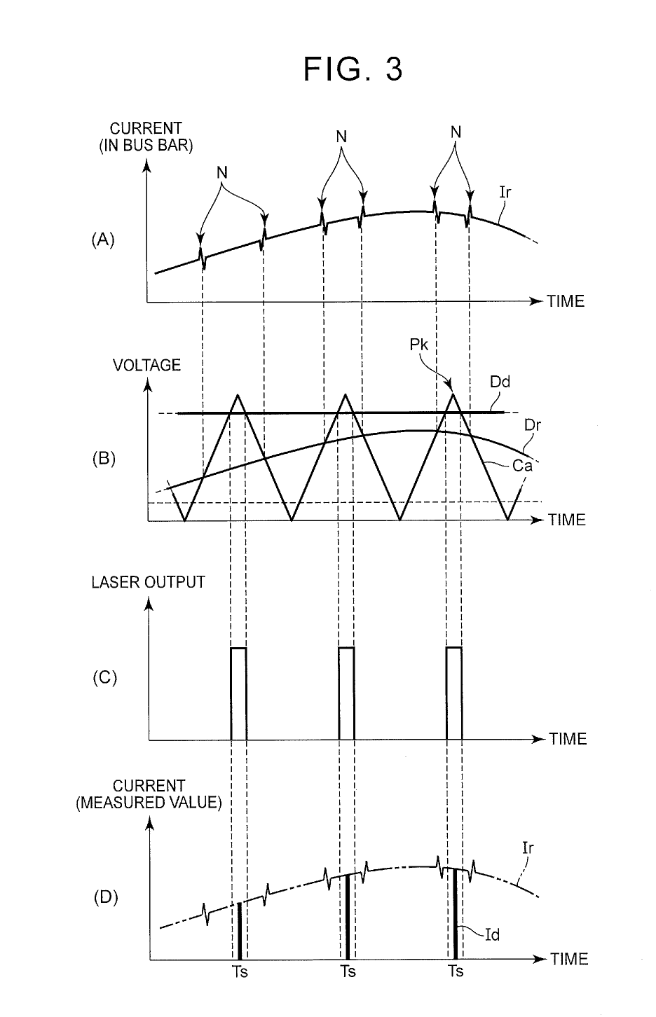

The laser light source 41 radiates a pulsed laser that is synchronized with a carrier signal of the inverter 5. The advantage of such radiation will be described. FIG. 3 consists of graphs showing a relationship among the output current of the inverter (FIG. 3(A)), the carrier signal (FIG. 3(B)), the pulsed laser (FIG. 3(C)), and the measured current (FIG. 3(D)). FIG. 3(B) shows a carrier signal Ca and a motor drive command Dr. The motor drive command Dr represents a waveform of the current desired to be supplied to the motor. The PWM generator 22 (see FIG. 1) compares the carrier signal Ca and the motor drive command Dr with each other, and generates a PWM signal whose pulse width corresponds to a period in which the carrier signal Ca is high. The PWM generator 22 supplies the generated PWM signal to each of the switching circuits. Each of the switching circuits repeats switching in accordance with the PWM signal, and the current Ir shown in FIG. 3(A) is output. The timing for switching is equivalent to an intersecting point of the carrier signal Ca and the motor drive command Dr, and a noise is generated in the output current Ir at this timing (see symbols N in FIG. 3(A)).

On the other hand, the controller 31 of the current sensor 30 generates a laser drive signal from the carrier signal Ca and a reference signal Dd with a constant voltage level (see FIG. 3(B) and FIG. (C)). The controller 31 compares the carrier signal Ca and the reference signal Dd with each other, and generates a laser drive signal whose pulse width corresponds to a period in which the voltage of the carrier, signal is higher than the voltage of the reference signal Dd (FIG. 3(C)). The laser light source 41 (see FIG. 2) radiates a pulsed laser corresponding to the laser drive signal. As is apparent from FIG. 3, the pulsed laser radiated by the laser light source 41 is synchronized with the carrier signal Ca of the inverter. More specifically, the pulsed laser radiated by the laser light source 41 is a pulse with a predetermined width around a peak Pk of the carrier signal Ca. The peak Pk of the carrier signal Ca does not coincide with the timing for switching. A laser is radiated between switching operations, and a current is measured. Symbols Ts in FIG. 3(D) indicate the timings for measuring the current. As shown in FIG. 3(D), each of the timings Ts for measuring the current Ir is between switching operations, and a measured current value Id is not influenced by the noise N. The same holds true for the sensor body 32 that measures a V-phase output current, and the sensor body 32 that measures a W-phase output current.

The inverter 5 is equipped with the three sensor bodies 32 that measure three output currents, namely, a U-phase output current, a V-phase output current, and a W-phase output current respectively. The laser drive signal supplied to all the sensor bodies is based on the single carrier signal Ca. Therefore, the inverter 5 can simultaneously measure three output currents, namely, a U-phase output current, a V-phase output current, and a W-phase output current.

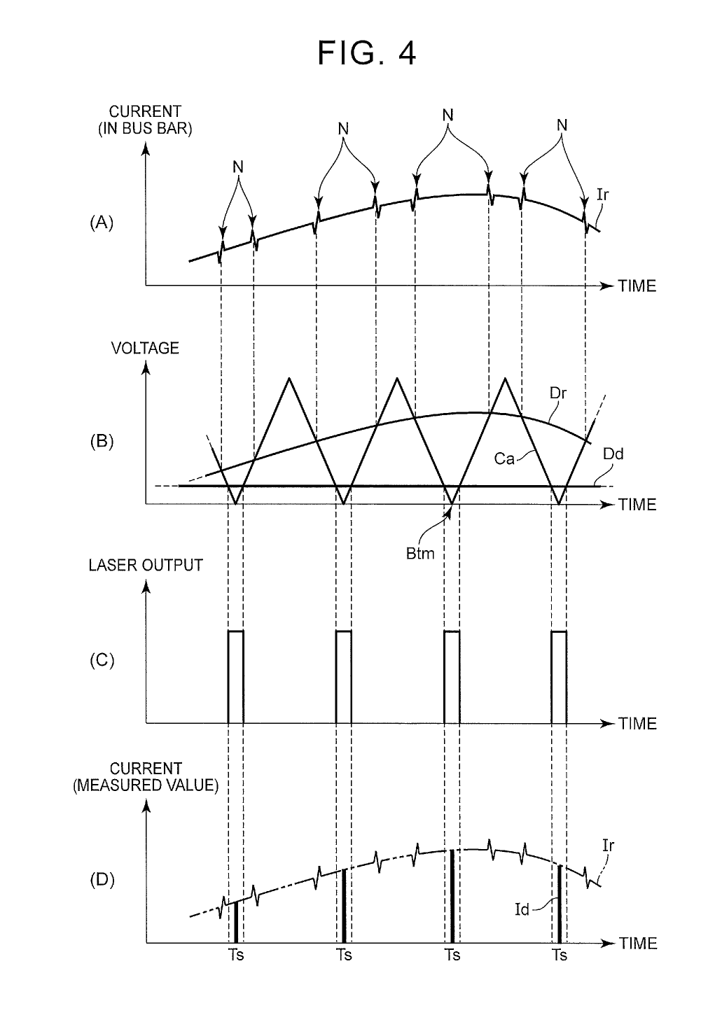

In the example of FIG. 3, the laser light source 41 radiates a pulsed laser including a peak timing of the carrier signal Ca. The same advantage is obtained even if the pulsed laser includes a bottom timing of the carrier signal Ca. FIG. 4 consists of graphs showing another example of the relationship among the output current signal including noise (FIG. 4(A)), the carrier signal (FIG. 4(B)), the pulsed laser (FIG. 4(C)), and the measured current value (FIG. 4(D)). In the example of FIG. 4, the controller 31 generates a laser drive signal using the low-level reference signal Dd. Concretely, the controller 31 compares the carrier signal Ca and the reference signal Dd with each other, and generates a laser drive signal whose pulse width corresponds to a period in which the voltage of the carrier signal is lower than the voltage of the reference signal Dd (FIG. 3(C)). On the other hand, as shown in FIG. 4(B), the PWM signal is a pulse signal that is determined by an intersecting point of the carrier signal Ca and the motor drive command Dr, and the intersecting point (i.e., a switching timing) does not coincide with a bottom Btm of the carrier signal Ca. Therefore, a current sensor that adopts a pulsed laser that is synchronized with the bottom Btm of the carrier signal Ca can measure a current at timings other than those when a switching noise is generated (see FIG. 4(D)). More specifically, in the example of FIG. 4, the laser light source 41 radiates a pulsed laser with a predetermined width around the bottom Btm of the carrier signal Ca. The width of the pulsed laser is determined by the level of the reference signal Dd.

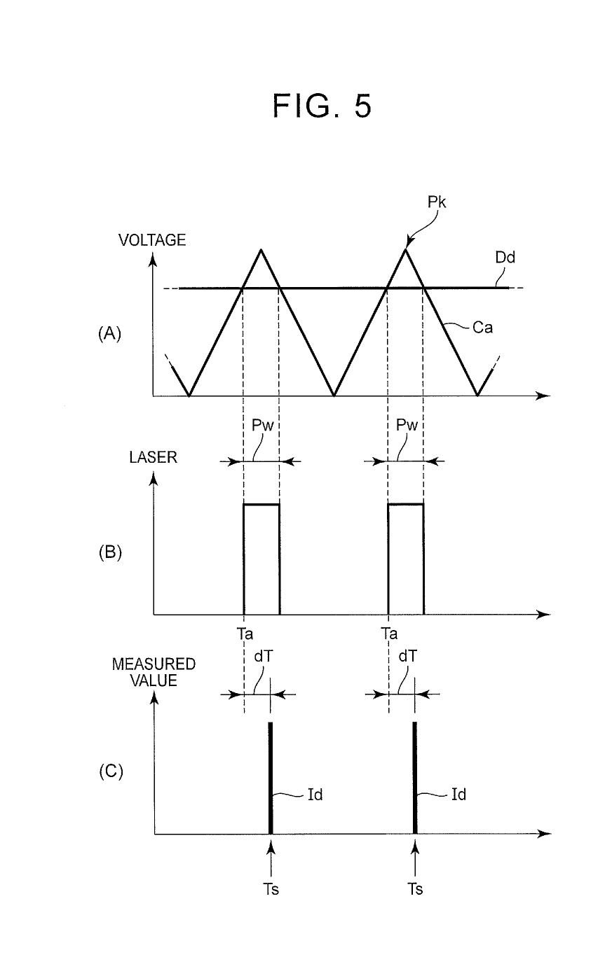

The points to remember about the art disclosed by the embodiment of the invention will be described. As shown in FIG. 3 and FIG. 4, the laser light source 41 radiates a pulsed laser that is synchronized with a carrier signal. The pulsed laser has a width Pw that is determined by the level of the reference signal Dd. It is desirable to set the width Pw of the pulsed laser as follows. FIG. 5 consists of graphs showing a relationship among the carrier signal Ca (FIG. 5(A)), the pulsed laser (FIG. 5(B)), and the timings Ts for measuring the current (FIG. 5(C)). In FIG. 5(B), timings when the pulsed laser rises are denoted by symbols Ta respectively. The pulsed laser begins to be radiated at each of these timings Ta. Besides, the laser detectors 44a and 44b start operation at each of these timings Ta. Each of the laser detectors 44a and 44b includes an AD converter that digitizes and fetches the intensity of a laser. In general, the AD converter takes a slightly long time in order to be activated. In FIG. 5(C), each delay time in activation is denoted by a symbol dT. The delay time is about 0.01 to 0.1 milliseconds, but a laser needs to be radiated during the delay time. As described above, the pulse width Pw of the pulsed laser depends on the level of the reference signal Dd. It is desirable to set the pulse width Pw of the pulsed laser as a time longer than the delay time dT of the laser detectors.

Other advantages of the current sensor 30 will be described. The laser light source 41 radiates a pulsed laser, and hence has a longer service life than in the case of a continuous wave laser. Besides, the laser light source 41 radiates a pulsed laser, and hence has a smaller heating value than in the case of a continuous wave laser.

In the embodiment of the invention, the current sensor that measures the output currents of the inverter has been described. The art disclosed by the present specification is characterized in that a pulsed laser is radiated at timings other than the switching timing. The art disclosed by the present specification is not limited to inverters, but is widely applicable to electric power converters having switching circuits. For example, in the inverter 5 shown in FIG. 1, the voltage converter circuit 12 is also equipped with switching circuits. Therefore, the art disclosed by the present specification is also effective in the case of measuring a current at an output (a point Q in FIG. 1) of the voltage converter circuit 12.

The representative and nonrestrictive concrete examples of the invention have been described in detail with reference to the drawings. This detailed description is simply intended to inform those skilled in the art of the details for carrying out the preferred examples of the invention, and is not intended to limit the scope of the invention. Besides, the additional features and inventions disclosed herein can be used independently of or in combination with other features and inventions, in order to provide a further improved current sensor and a further improved electric power converter.

Besides, the combination of the features and processes disclosed in the foregoing detailed description is not indispensable in carrying out the invention in a broadest sense, but is mentioned merely for the purpose of describing the representative concrete examples of the invention in particular. Furthermore, the various features of the foregoing representative concrete examples and the various features of what is set forth in the independent and dependent claims should not necessarily be combined in accordance with the concrete examples mentioned herein or according to the sequence of citation, in providing any additional and useful embodiment of the invention.

All the features described in the present specification and/or the claims are intended to be disclosed individually or independently of one another as restrictions on the disclosure upon the filing of the application and the specific matters set forth in the claims, apart from the configuration of the features described in the embodiment of the invention and/or the claims. Furthermore, all the numerical ranges and groups or assemblages are described with the intention of disclosing a configuration in between, as restrictions on the disclosure upon the filing of the application and the specific matters set forth in the claims.

The concrete examples of the invention have been described above in detail, but these are nothing more than exemplifications, and do not limit the claims. The art set forth in the claims encompasses various modifications and alterations of the concrete examples exemplified above. Besides, the technical elements described in the present specification or the drawings are technically useful alone or in various combinations, and are not limited to the combination set forth in the claims at the time of the filing of the application. Besides, the art exemplified in the present specification or the drawings achieves a plurality of objects at the same time, and is technically useful by achieving one of the objects alone.

1-6. (canceled)

7. A current sensor for measuring an output current of a switching circuit, the sensor comprising:
a magneto-optical element that is arranged at a current measurement point;
a light source that radiates light onto the magneto-optical element;
a light receiver that receives at least one of transmitted light of the magneto-optical element and reflected light of the magneto-optical element; and
a controller configured to calculate a current value at the measurement point from a polarization state of received light, wherein
the light source is pulsed light that is synchronized with a carrier signal of the switching circuit, and
the light source radiates the pulsed light that includes a timing of a peak or bottom of the carrier signal.

8. The current sensor according to claim 7, wherein
the light source radiates the pulsed light around the timing of the peak or bottom of the carrier signal.

9. An electric power converter comprising:
the switching circuit and the current sensor according to claim 7.

10. The electric power converter according to claim 9, wherein
the electric power converter is an inverter that includes the current sensor that measures output alternating currents of three phases UVW by three light sources that are synchronized with a single carrier signal, the output alternating currents of the three phases UVW are a U-phase output alternating current, a V-phase output alternating current and a W-phase output alternating current.

11. An electric power converter comprising:
the switching circuit and the current sensor according to claim 8.

12. The electric power converter according to claim 11, wherein
the electric power converter is an inverter that includes the current sensor that measures output alternating currents of the three phases UVW by three light sources that are synchronized with a single carrier signal, the output alternating currents of three phases UVW are a U-phase output alternating current, a V-phase output alternating current and a W-phase output alternating current.
